(19) United States
(12) Patent Application Publication
(10) Pub. No.: US 2025/0361641 A1
(43) Pub. Date: Nov. 27, 2025

(54) COPPER FOIL FOR PRINTED CIRCUIT BOARDS AND MANUFACTURING METHOD THEREOF

(71) Applicant: NAN YA PLASTICS CORPORATION, Taipei City (TW)

(72) Inventors: Ching-Yao Yuan, Taipei City (TW); Wei-Sheng Cheng, Taipei City (TW); Yu-Chi Hsieh, Taipei City (TW)

(73) Assignee: NAN YA PLASTICS CORPORATION, Taipei City (TW)

(21) Appl. No.: 18/746,067

(22) Filed: Jun. 18, 2024

(30) Foreign Application Priority Data
May 23, 2024 (TW) 113119000

(51) Int. Cl. C25D 3/38; C25D 5/10; C25D 21/02; C25D 21/12; H05K 1/09; H05K 3/02

(52) U.S. Cl. CPC C25D 3/38; C25D 5/10; C25D 21/02; C25D 21/12; H05K 1/09; H05K 3/025; H05K 2201/0355; H05K 2203/0307; H05K 2203/0723

(57) ABSTRACT

The disclosure provides a copper foil for printed circuit boards and a manufacturing method thereof. The manufacturing method includes performing a multi-stage electroplating process to sequentially form a metal release layer, a burnt copper layer, and a copper sulfate layer. The multi-stage electroplating process includes a metal release layer electroplating process, a copper pyrophosphate electroplating process, and a copper sulfate electroplating process.

### CROSS-REFERENCE TO RELATED APPLICATION

This application claims the priority benefit of Taiwan application serial no. 113119000, filed on May 23, 2024. The entirety of the above-mentioned patent application is hereby incorporated by reference herein and made a part of this specification.

### BACKGROUND

### Technical Field

The disclosure relates to a copper foil and a manufacturing method thereof, and in particular to a copper foil for printed circuit boards and a manufacturing method thereof.

### Description of Related Art

An ultra-thin copper foil is widely used in printed circuit boards (PCB) for electronic and electrical materials. For the ultra-thin copper foil products for PCB thin circuits, when there are pinholes in the ultra-thin copper foil, the pinholes may cover the PCB circuit, causing circuit failure. Therefore, the ultra-thin copper foil must be pinhole-free. In the prior art, the electroplating section of the ultra-thin copper foil is usually one-stage electroplating, or at most two-stage electroplating. The electroplating condition of one-stage electroplating is single and cannot be changed. The electroplating layer is easily to be unable to form a dense and uniform layer. Therefore, plating pinholes are easily formed.

Based on the above, developing a pinhole-free process for the ultra-thin copper foil to achieve a pinhole-free ultra-thin copper foil is an issue for those skilled in the art.

### SUMMARY

The disclosure provides a copper foil for printed circuit boards and a manufacturing method thereof. The manufacturing method may produce an ultra-thin copper foil for printed circuit boards without pinholes to avoid an issue of circuit failure caused by the pinholes.

The manufacturing method of the copper foil for printed circuit boards of the disclosure includes performing a multi-stage electroplating process to sequentially form a metal release layer, a burnt copper layer, and a copper sulfate layer. The multi-stage electroplating process includes a metal release electroplating process, a copper pyrophosphate electroplating process, and a copper sulfate electroplating process.

In an embodiment of the disclosure, the metal release layer includes Ni, W, Zn, Mo, Co, or a combination thereof.

In an embodiment of the disclosure, an electroplating condition of the metal release electroplating process is 2 ASD to 20 ASD. A time is 2 seconds to 20 seconds. The metal release electroplating process is 2-stage to 6-stage electroplating. An electroplating temperature is 25° C. to 60° C.

In an embodiment of the disclosure, a thickness of the metal release layer is 10 nm to 300 nm.

In an embodiment of the disclosure, a thickness of the burnt copper layer is 10 nm to 300 nm.

In one embodiment of the disclosure, a formula of the burnt copper layer is 5 g/L to 25 g/L of copper pyrophosphate ions, 100 to 300 g/L of potassium pyrophosphate, and NH₃OH controlled pH 9 to 10.

In an embodiment of the disclosure, the electroplating condition of the copper pyrophosphate electroplating process is 2 ASD to 20 ASD. The time is 2 seconds to 20 seconds. The copper pyrophosphate electroplating process is 2-stage to 6-stage electroplating. The electroplating temperature is 25° C. to 60° C.

In an embodiment of the disclosure, the formula of the copper sulfate layer is 70 g/L to 90 g/L of copper ions and 60 g/L to 150 g/L of sulfuric acid.

In an embodiment of the disclosure, the electroplating condition of the copper sulfate electroplating process is 5 ASD to 30 ASD. The time is 2 seconds to 20 seconds. The copper sulfate electroplating process is 4-stage to 8-stage electroplating.

In an embodiment of the disclosure, the thickness of the copper sulfate layer is 1.5 μm to 3 μm.

The copper foil for printed circuit boards of the disclosure is produced by the manufacturing method of the copper foil for printed circuit boards.

Based on the above, the disclosure provides the copper foil for printed circuit boards and the manufacturing method thereof. The manufacturing method utilizes the multi-stage electroplating process. The multi-stage electroplating process includes the metal release electroplating process, the copper pyrophosphate electroplating process, and the copper sulfate electroplating process. In this way, an electroplating layer may be made dense and uniform, so that no pinholes are generated between the electroplating layers.

### DESCRIPTION OF THE EMBODIMENTS

Hereinafter, an embodiment of the disclosure will be described in detail. However, these embodiments are exemplary, and the disclosure is not limited thereto.

Herein, a range indicated by “one value to another value” is a general representation which avoids enumerating all values in the range in the specification. Therefore, the record of a specific value range, any number within this numerical range and any smaller numerical range bounded by any number within that numerical range is contemplated as if such any number and such smaller numerical ranges were expressly written in the specification.

The disclosure provides a manufacturing method for copper foil for printed circuit boards, including performing a multi-stage electroplating process to sequentially form a metal release layer, a burnt copper layer, and a copper sulfate layer. The multi-stage electroplating process includes a metal release electroplating process, a copper pyrophosphate electroplating process, and a copper sulfate electroplating process.

In this embodiment, a component of the metal release layer may be composed of multiple components, and may include Ni, W, Zn, Mo, Co, or a combination thereof. An electroplating condition of the metal release electroplating process is, for example, 2 ASD to 20 ASD. A time is, for example, 2 seconds to 20 seconds. The metal release electroplating process is, for example, 2-stage to 6-stage electroplating. An electroplating temperature is, for example, 25° C. to 60° C. A formula of the burnt copper layer is, for example, 5 g/L to 25 g/L of copper pyrophosphate ions, 100 to 300 g/L of potassium pyrophosphate, and the NH₃OH controlled pH is, for example, 9 to 10. The electroplating condition of the copper pyrophosphate electroplating process is, for example, 2 ASD to 20 ASD. The time is, for example, 2 seconds to 20 seconds. The copper pyrophosphate electroplating process is, for example, 2-stage to 6-stage electroplating. The electroplating temperature is, for example, 25° C. to 60° C. The formula of the copper sulfate layer is, for example, 70 g/L to 90 g/L of copper ions and 60 g/L to 150 g/L of sulfuric acid. The electroplating condition of the copper sulfate electroplating process is, for example, 5 ASD to 30 ASD. The time is, for example, 2 seconds to 20 seconds. The copper sulfate electroplating process is, for example, 4-stage to 8-stage electroplating. A thickness of the metal release layer is, for example, 10 nm to 300 nm. The thickness of the copper sulfate layer is, for example, 1.5 μm to 3 μm.

In this embodiment, before performing the multi-stage electroplating process, pickling and chromic acid processes may be sequentially performed, and after the multi-stage electroplating process, roughening, chromic acid, and silane treatment may be sequentially performed. Process conditions of the pickling and chromic acid processes and the roughening, chromic acid, and silane treatment are all commonly known conditions, which may be adjusted by those skilled in the art according to actual operating conditions, and thus are not repeated herein. In more detail, the condition of pickling is, for example, sulfuric acid 90-110 g/L 10S; the condition of chromic acid is, for example, chromium 3-6 g/L 10S; the condition of roughening is, for example, Cu⁺² 8-20 g/L 60ASD-80 ASD 2-3S, Cu⁺² 40-60 g/L 10ASD-30 ASD 15-30S. A heat-resistant metal layer contains Ni, W, Zn, Mo, and Co, and has a thickness of, for example, 1 nm to 5 nm. As for the silane treatment, silane is used with appropriate prepreg.

The disclosure also provides a copper foil for printed circuit boards, which is made by the manufacturing method of the copper foil for printed circuit boards. The copper foil for printed circuit boards sequentially includes the metal release layer, the burnt copper layer, and the copper sulfate layer.

Hereinafter, the copper foil for printed circuit boards and the manufacturing method thereof proposed in the embodiments will be described in detail through experimental examples. However, the following experimental examples are not intended to limit the disclosure.

As may be seen from Table 1 below, Embodiments 1 to 4 adopt the manufacturing method of copper foil for printed circuit boards of the disclosure and use the multi-stage electroplating process to form a electroplating layer having the metal release layer, the burnt copper layer, and the copper sulfate. In this way, the electroplating layer may be made dense and uniform, so that no pinholes are generated between the electroplating layers, and an ultra-thin copper foil for printed circuit boards without pinholes may be produced, thereby avoiding an issue of circuit failure caused by the pinholes. In comparison, Comparative Example 1 and Comparative Example 2 do not use the manufacturing method of the copper foil for printed circuit boards of the disclosure. Therefore, a peeling force is uneven to form holes and generate the pinholes, which may lead to the issue of circuit failure caused by the pinholes.

TABLE 1

| | | | burnt | | copper | | |
|---|---|---|---|---|---|---|---|
| | metal release | | copper | | sulfate | | |
| | layer (NiCo) | | layer | | layer | | pinhole |
| Embodiment 1 | 0.5 | ASD | 0.6 | ASD | 20 | ASD | without |
| | 15 | S | 15 | S | 19 | S | pinholes |
| | 2 | ASD | 1.8 | ASD | 5 | ASD | |
| | 15 | S | 30 | S | 59 | S | |
| Embodiment 2 | 0.5 | ASD | 0.6 | ASD | 20 | ASD | without |
| | 15 | S | 15 | S | 19 | S | pinholes |
| | 1 | ASD | 0.9 | ASD | 5 | ASD | |
| | 5 | S | 15 | S | 59 | S | |
| | 0.5 | ASD | 0.9 | ASD | | | |
| | 5 | S | 15 | S | | | |
| Embodiment 3 | 0.5 | ASD | 0.6 | ASD | 20 | ASD | without |
| | 15 | S | 15 | S | 19 | S | pinholes |
| | 2 | ASD | 0.9 | ASD | 5 | ASD | |
| | 15 | S | 15 | S | 59 | S | |
| | | | 0.9 | ASD | | | |
| | | | 15 | S | | | |
| Embodiment 4 | 0.5 | ASD | 0.6 | ASD | 10 | ASD | without |
| | 15 | S | 15 | S | 19 | S | pinholes |
| | 2 | ASD | 1.8 | ASD | 5 | ASD | |
| | 15 | S | 30 | S | 30 | S | |
| | | | | | 5 | ASD | |
| | | | | | 30 | S | |
| Comparative | 2 | ASD | 0.6 | ASD | 20 | ASD | peeling force |
| Example 1 | 1.5 | S | 15 | S | 38 | S | is uneven to |
| | | | 1.8 | ASD | | | form holes |
| | | | 30 | S | | | |
| Comparative | 0.5 | ASD | 0.6 | ASD | 20 | ASD | number of |
| Example 2 | 15 | S | 15 | S | 38 | S | pinholes >300 |

| | | |
|---|---|---|
| 2 | ASD | hole/m2 |
| 15 | S | |

In summary, the disclosure provides the copper foil for printed circuit boards and the manufacturing method thereof. The manufacturing method utilizes the multi-stage electroplating process. The multi-stage electroplating process includes the metal release electroplating process, the copper pyrophosphate electroplating process, and the copper sulfate electroplating process to form the electroplating layer with the metal release layer, the burnt copper layer, and the copper sulfate layer. In this way, the electroplating layer may be made dense and uniform, so that no pinholes are generated between the electroplating layers, and the ultra-thin copper foil for printed circuit without pinholes may be produced, thereby avoiding the issue of circuit failure caused by the pinholes.

What is claimed is:

1. A manufacturing method of a copper foil for printed circuit boards, comprising:
performing a multi-stage electroplating process to sequentially form a metal release layer, a burnt copper layer, and a copper sulfate layer,
wherein the multi-stage electroplating process comprises a metal release electroplating process, a copper pyrophosphate electroplating process, and a copper sulfate electroplating process.

2. The manufacturing method of the copper foil for printed circuit boards according to claim 1, wherein a component of the metal release layer comprises Ni, W, Zn, Mo, Co, or a combination thereof.

3. The manufacturing method of the copper foil for printed circuit boards according to claim 1, wherein an electroplating condition of the metal release electroplating process is 2 ASD to 20 ASD, a time is 2 seconds to 20 seconds, the metal release electroplating process is 2-stage to 6-stage electroplating, and an electroplating temperature is 25 to 60° C.

4. The manufacturing method of the copper foil for printed circuit boards according to claim 1, wherein a thickness of the metal release layer is 10 nm to 300 nm.

5. The manufacturing method of the copper foil for printed circuit boards according to claim 1, wherein a formula of the burnt copper layer is 5 g/L to 25 g/L of copper pyrophosphate ions, 100 to 300 g/L of potassium pyrophosphate, and NH₃OH controlled pH 9 to 10.

6. The manufacturing method of the copper foil for printed circuit boards according to claim 1, wherein a thickness of the burnt copper layer is 10 nm to 300 nm.

7. The manufacturing method of the copper foil for printed circuit boards according to claim 1, an electroplating condition of the copper pyrophosphate electroplating process is 2 ASD to 20 ASD, a time is 2 seconds to 20 seconds, the copper pyrophosphate electroplating process is 2-stage to 6-stage electroplating, and an electroplating temperature is 25 to 60° C.

8. The manufacturing method of the copper foil for printed circuit boards according to claim 1, wherein a formula of the copper sulfate layer is 70 g/L to 90 g/L of copper ions and 60 g/L to 150 g/L of sulfuric acid.

9. The manufacturing method of the copper foil for printed circuit boards according to claim 1, an electroplating condition of the copper sulfate electroplating process is 5 ASD to 30 ASD, a time is 2 seconds to 20 seconds, and the copper sulfate electroplating process is 4-stage to 8-stage electroplating.

10. The manufacturing method of the copper foil for printed circuit board according to claim 1, wherein a thickness of the copper sulfate layer is 1.5 μm to 3 μm.

11. A copper foil for printed circuit boards, made by the manufacturing method for the copper foil for printed circuit boards according to claim 1.
